(19) United States
(12) Patent Application Publication
(10) Pub. No.: US 2026/0173875 A1
(43) Pub. Date: Jun. 18, 2026

(54) BACKSIDE POWER DELIVERY NETWORK (BSPDN) WITH PILLAR EMBEDDED IN COOLING CHANNEL

(71) Applicant: International Business Machines Corporation, Armonk, NY (US)

(72) Inventors: Joshua Mark Rubin, Albany, NY (US); Qianwen Chen, Fort Collins, CO (US); Tao Li, Slingerlands, NY (US); Ruilong Xie, Niskayuna, NY (US)

(21) Appl. No.: 18/981,461

(22) Filed: Dec. 14, 2024

(51) Int. Cl. H01L 23/46; H01L 23/00; H01L 23/13

(52) U.S. Cl. CPC H10W 40/40; H10W 70/68; H10W 72/331; H10W 74/15; H10W 90/724; H10W 90/734

(57) ABSTRACT

A semiconductor structure includes a backside power delivery network (BSPDN) having a back-end-of-line (BEOL) wiring layer, a package coupled to the BSPDN proximate to the BEOL wiring layer, a dielectric layer located between the BSPDN and the package, a coolant inlet and a coolant outlet, and a cavity located within at least one of the package and the dielectric layer. The cavity is in fluid communication with the coolant inlet and the coolant outlet. A plurality of pillars are coupled to and extend from the BSPDN at the BEOL wiring layer, in which a first pillar, of the plurality of pillars, is located in and surrounded by the dielectric layer and a second pillar, of the plurality of pillars, resides within the cavity.

### BACKGROUND

The present disclosure generally relates to the fabrication of integrated circuits, semiconductors, and the like and, more particularly, to various methods of forming a pillar embedded within a cooling channel of a backside power delivery network (BSPDN).

Previously, both power and signal interconnects have been formed at the frontside of a substrate of a semiconductor device. In some cases, to free up space at the frontside of the substrate and/or to allow for additional interconnections, the power connections of the semiconductor device can be formed at the backside of the substrate (backside power delivery network (BSPDN)). Beneficially, implementing a BSPDN in a semiconductor device can: increase the available real estate for potential additional interconnections, reduce wiring routing congestion, and/or reduce signal interference at the frontside of the substrate. Further, forming the power connections on the backside of the substrate can allow for the power connections to be larger, and therefore less resistive, than the previous frontside power connections. As such, improvements in power integrity and enhancements in performance have been observed in practice.

Semiconductor devices that include a BSPDN typically include a device layer surrounded by isolation materials and sandwiched between the frontside signal interconnections and the backside power interconnections. During operation of the semiconductor device, the temperature of the device layer can increase. Increases in temperatures past a threshold of any of the devices within the device layer can potentially cause deterioration of the devices, thus reducing the integrity of the device and resulting in errors and potential premature failure of the semiconductor device.

### BRIEF SUMMARY

Principles of the invention provide techniques for a backside power delivery network (BSPDN) with a pillar embedded in a cooling channel. In one aspect, an exemplary semiconductor structure includes a backside power delivery network (BSPDN) having a back-end-of-line (BEOL) wiring layer, a package coupled to the BSPDN proximate to the BEOL wiring layer, a dielectric layer located between the BSPDN and the package, a coolant inlet and a coolant outlet, and a cavity located within at least one of the package and the dielectric layer. The cavity being in fluid communication with the coolant inlet and the coolant outlet. A plurality of pillars is coupled to and extend from the BSPDN at the BEOL wiring layer, in which a first pillar, of the plurality of pillars, is located in and surrounded by the dielectric layer and a second pillar, of the plurality of pillars, resides within the cavity.

Another aspect of an exemplary semiconductor structure includes a backside power delivery network (BSPDN) having a back-end-of-line (BEOL) wiring layer, a substrate coupled to the BSPDN proximate to the BEOL wiring layer, a cavity within the substrate, one or more terminal pads connected to the BSPDN, and one or more pillars coupled to the one or more terminal pads and extending from a surface of the BSPDN toward the cavity of the substrate.

Still another aspect of an exemplary semiconductor structure includes a backside power delivery network (BSPDN) having a back-end-of-line (BEOL) wiring layer, an interposer coupled to the BSPDN proximate to the BEOL wiring layer, a cavity extending from a surface of the interposer and, at least partially, into the interposer, and a plurality of pillars. A first pillar, of the plurality of pillars, extends from the BSPDN to the interposer, in which the first pillar is electrically connected to the BEOL wiring layer of the BSPDN and a wiring layer of the interposer and a second pillar, of the plurality of pillars, is coupled to and extends from the BSPDN toward the cavity of the interposer.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide for a high efficiency cooling approach to release and dissipate heat away from a temperature sensitive device of a semiconductor structure that includes a backside power delivery network (BSPDN), improving reliability and performance of the device, and thus the semiconductor structure:
by using a backside back-end-of-line (BS BEOL) and metal pillar to create a metal cooling/thermal dissipation path,
by building a metal cooling/thermal dissipation path close to heat generating devices, such as those formed in a device layer of a backside power delivery network (BSPDN) die,
by forming a recessed cavity within a dielectric layer in which at least one metal pillar of a metal cooling/thermal dissipation path resides within the recessed cavity,
by coupling to a backside power delivery network (BSPDN) die a package, a substrate, and/or an interposer that includes a cavity aligning with a recessed cavity of a dielectric layer of the BSPDN die, cooperatively forming a single cavity, in which at least one metal pillar of a metal cooling/thermal dissipation path resides within the single cavity,
by coupling an extension pillar to at least one metal pillar of a metal cooling/thermal dissipation path to further draw heat away from heat generating devices within a backside power delivery network (BSPDN) die,
by providing thermal protection in semiconductor devices including a BSPDN,
by providing heat release to a dielectric coolant though a metal cooling/thermal dissipation path, and
by forming a cooling channel in a dielectric layer of a backside power delivery network (BSPDN) die and/or a package, and/or a substrate, and/or interposer coupled to the BSPDN die and exposing a metal cooling/thermal dissipation path to the cooling channel.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 illustrates a prior art backside power delivery network (BSPDN) device;

FIG. 2 illustrates an embodiment of a backside power delivery network (BSPDN) with a pillar embedded in a cooling channel, according to an aspect of the invention;

FIGS. 3-9 illustrate an exemplary process for manufacturing a backside power delivery network (BSPDN) with a pillar embedded in a cooling channel, according to an aspect of the invention;

FIG. 10 illustrates an exemplary process for manufacturing a backside power delivery network (BSPDN) with a pillar and an extension pillar embedded in a cooling channel, according to an aspect of the invention;

FIG. 11 illustrates an embodiment of a backside power delivery network (BSPDN) with a pillar embedded in a cooling channel, according to an aspect of the invention;

FIG. 12 illustrates an embodiment of a backside power delivery network (BSPDN) with a pillar embedded in a cooling channel, according to an aspect of the invention;

FIG. 13 illustrates an embodiment of a backside power delivery network (BSPDN) with a pillar embedded in a cooling channel, according to an aspect of the invention;

FIG. 14 illustrates a top view of an embodiment of a backside power delivery network (BSPDN) with a pillar embedded in a cooling channel, according to an aspect of the invention;

FIG. 15 illustrates a cross-section view of an embodiment of a backside power delivery network (BSPDN) with a pillar embedded in a cooling channel, according to an aspect of the invention; and

FIG. 16 illustrates an exemplary block diagram of a cooling system for a backside power delivery network (BSPDN) with a pillar embedded in a cooling channel, according to an aspect of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Standard semiconductor devices without a backside power delivery network (BSPDN) can have a low thermal resistance to a substrate, such as a silicon substrate for example, which can be attached to a heat sink to aid in heat dissipation. However, in the case of a semiconductor device with a BSPDN, the device layer is sandwiched between BEOL wiring on the front and backside of the of the device without a direct thermal path to a carrier. Copper (Cu) is a good thermal conductor, but dielectrics are not, and the path thus can be circuitous and indirect. A net result can be that a device with a BSPDN typically does not have equivalent thermal resistance compared to a device without a BSPDN.

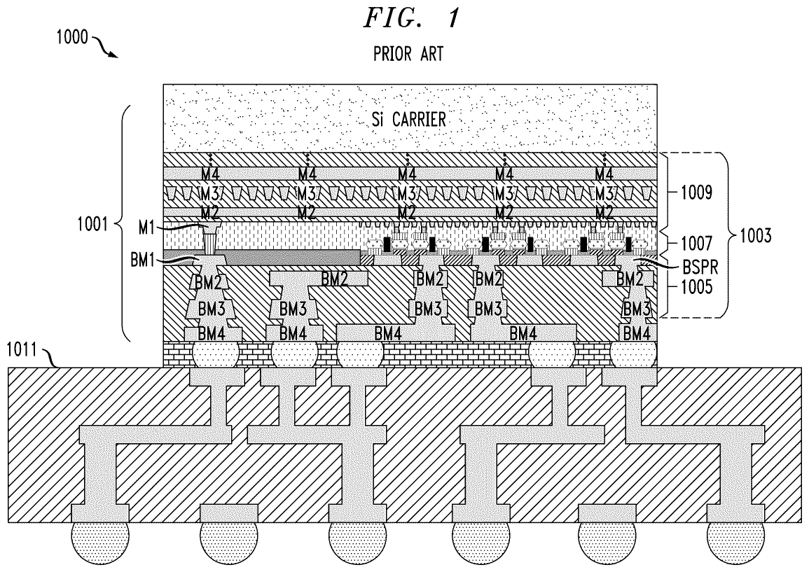

Referring now to FIG. 1, there is shown a prior art semiconductor structure 1000 including a backside power delivery network (BSPDN) die 1001, which includes a back-end-of-line (BEOL) wiring layer 1003 having a frontside BEOL (FS BEOL) wiring layer 1009; a device layer 1007; and a backside BEOL (BS BEOL) wiring layer 1005, coupled to a package 1011 such as a substrate and/or an interposer.

One or more embodiments advantageously provide a semiconductor structure with a metal cooling/thermal dissipation path formed close to heat generating devices. In some embodiments, a cooling channel can be formed in a dielectric layer of a backside power delivery network (BSPDN) die and/or a package, such as a substrate and/or an interposer, coupled to the BSPDN die, exposing a metal cooling/thermal dissipation path to the cooling channel. In one or more embodiments, the metal cooling/thermal dissipation path can provide heat release to a dielectric coolant. Heat can be drawn away from heat generating devices in a high efficiency cooling approach, releasing and dissipating the heat, improving reliability and performance of the semiconductor structure.

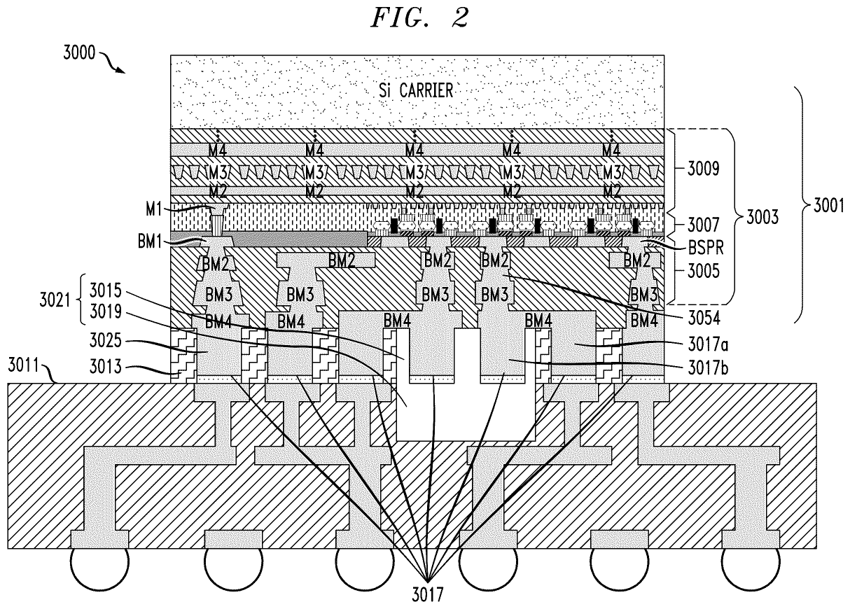

Consider now an exemplary semiconductor structure. Referring to FIG. 2, an embodiment of a semiconductor structure 3000 is illustrated. The semiconductor structure 3000 can include a die with a backside power delivery network (BSPDN) 3001 including a back-end-of-line (BEOL) wiring layer 3003. In some embodiments, the BEOL wiring layer 3003 can have a frontside BEOL (FS BEOL) wiring layer 3009, a device layer 3007, and a backside BEOL (BS BEOL) wiring layer 3005. Coupled to the BSPDN die 3001, at the BS BEOL wiring layer 3005, can be terminal pads 3025 and a dielectric layer 3013. Additionally, a plurality of pillars 3017 can be coupled to the terminal pads 3025 and can extend from the BSPDN die 3001.

A first pillar 3017a of the plurality of pillars 3017 can be located in and surrounded by the dielectric layer 3013. In some embodiments, the first pillar 3017a can be electrically connected to the BEOL wiring layer 3003. Further, more specifically, in one or more embodiments, the first pillar 3017a can be electrically connected to the BS BEOL wiring layer 3005 of the BEOL wiring layer 3003. Further, the BSPDN die 3001 can be coupled to a substrate 3011 and the first pillar 3017a can be electrically connected to the substrate 3011 coupled to the BSPDN die 3001, though examples are not so limited and the first pillar 3017a can be electrically connected to a package, such as an interposer. In some embodiments, the substrate 3011 can be a glass substrate, a silicon substrate, or an organic substrate, though embodiments are not so limited.

In some embodiments, the dielectric layer 3013 can include a recessed cavity 3015 within the dielectric layer 3013. In some embodiments, the recessed cavity 3015 can be, at least, partially recessed and in still other embodiments, the recessed cavity 3015 can be fully recessed. For example, a fully recessed cavity 3015 can include recessing the cavity 3015 completely through the dielectric layer 3013. A second pillar 3017b of the plurality of pillars 3017 can be embedded in or reside within the recessed cavity 3015 within the dielectric layer 3013. In some embodiments, the second pillar 3017b can be connected to the BEOL wiring layer 3003. Further, more specifically, in one or more embodiments, the second pillar 3017b can be connected to the BS BEOL wiring layer 3005 of the BEOL wiring layer 3003. Additionally, in some nonlimiting embodiments, the second pillar 3017b can be electrically isolated from the first pillar 3017a.

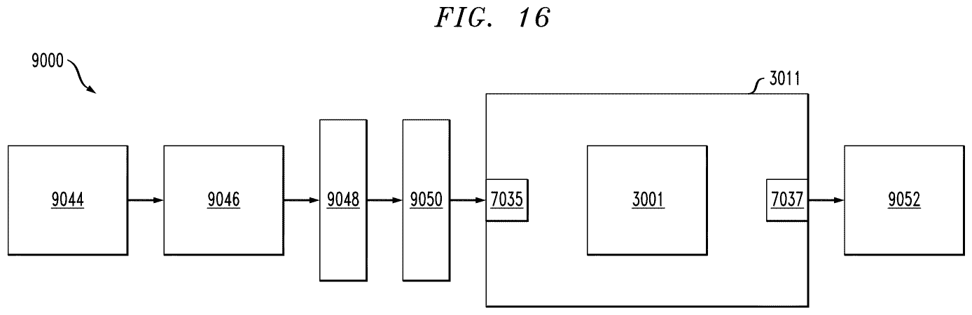

The second pillar 3017b can be thermally connected to the device layer 3007 of the BSPDN die 3001. This connection can create a metal cooling/thermal dissipation path 3054. Heat generated by the device layer 3007 of the BEOL wiring layer 3003 of the BSPDN die 3001, during operation of the semiconductor structure 3000, can be released from and dissipated away from the device layer 3007 through the thermal connection of the second pillar 3017b to the device layer 3007 (e.g., through the metal cooling/thermal dissipation path 3054). As will be described in further detail herein, this metal cooling/thermal dissipation path 3054 can be connected to a liquid cooling channel (e.g., cooling channel 8033 as shown in FIG. 15) via the second pillar 3017b. The liquid cooling channel can include a dielectric coolant. Accordingly, heat can be dissipated away from the device layer 3007 and to the liquid cooling channel via the second pillar 3017b. Additionally, some heat generated by the BSPDN die 3001 can potentially dissipate in the substrate 3011 via the first pillar 3017a.

As illustrated in FIG. 2, the substrate 3011 can be coupled to the dielectric layer 3013, opposite the BSPDN die 3001. In some embodiments, the substrate 3011 can include a cavity 3019. The dielectric layer 3013 and the substrate 3011 can be coupled so as the recessed cavity 3015 of the dielectric layer 3013 and the cavity 3019 of the substrate 3011 cooperatively forming a single cavity 3021. In some embodiments, the second pillar 3017b can be embedded in or reside within the single cavity 3021. Further, in one or more embodiments, the cavity 3019 of the substrate 3011 can be a cooling channel that includes a coolant inlet and a coolant outlet (e.g., cooling channel 8033, coolant inlet 7035, and coolant outlet 7037 of FIG. 15), as will be described in further detail here within.

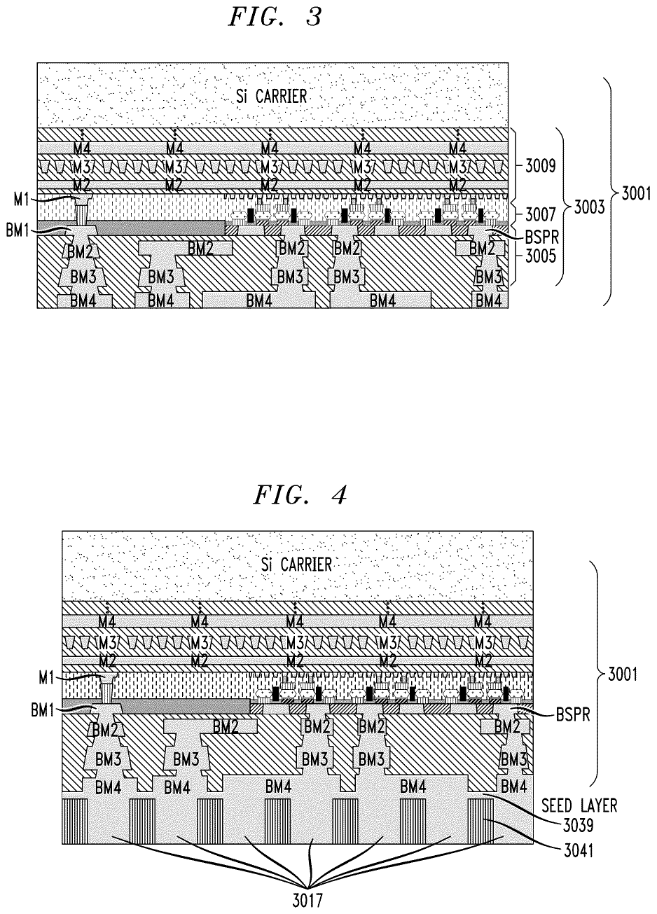

Referring now to FIGS. 3-9, according to some aspects, in the method of manufacturing a semiconductor structure, according to the embodiment of FIG. 2, a backside power delivery network (BSPDN) die 3001 including a back-end-of-line (BEOL) wiring layer 3003 having a frontside BEOL (FS BEOL) wiring layer 3009, a device layer 3007, and a backside BEOL (BS BEOL) wiring layer 3005, can be formed, as shown in FIG. 3.

In some embodiments, the FS BEOL wiring layer 3009 can include one or more interconnect dielectric material layers including one or more conductive lines (i.e., interconnects, wiring, etc.). Additionally, in some embodiments, the BS BEOL wiring layer 3005 can include one or more interconnect dielectric material layers including one or more conductive lines (i.e., interconnects, wiring, etc.). The device layer 3007 can be sandwiched between the FS BEOL wiring layer 3009 and the BS BEOL wiring layer 3005. The device layer 3007 can include one or more devices such as transistors, resistors, capacitors, diodes, etc.

In some examples, the conductive lines of the FS BEOL wiring layer 3009 and the BS BEOL wiring layer 3005 can include Copper (Cu), though examples are not so limited, and the conductive lines can include any electrically conductive material or metal alloy known in the art. In some embodiments, the conductive lines of the FS BEOL wiring layer 3009 can include signal lines and the conductive lines of the BS BEOL wiring layer 3005 can include power lines. A frontside dielectric layer can surround the signal lines and a backside dielectric layer can surround the power lines.

Additionally, the FS BEOL wiring layer 3009 and the BS BEOL wiring layer 3005 can include vias formed and orientated approximately perpendicular to the conductive lines of the FS BEOL wiring layer 3009 and the conductive lines of the BS BEOL wiring layer 3005. In some embodiments, the vias can extend between conductive lines within the FS BEOL wiring layer 3009 and/or between one or more conductive lines of the FS BEOL wiring layer 3009 and the device layer 3007. Further, in some embodiments, the vias can extend between conductive lines within the BS BEOL wiring layer 3005 and/or between one or more conductive lines of the BS BEOL wiring layer 3005 and the device layer 3007. Further still, in some embodiments, the vias can extend between one or more conductive lines of the FS BEOL wiring layer 3009 and one or more conductive lines of the BS BEOL wiring layer 3005. Accordingly, one via can begin and/or terminate on different conductive lines than another via. Further, vias throughout the BEOL wiring layer 3003 can differ in size (such as width), cross-sectional shape, material, etc. For example, one or more vias can include Cu, Ruthenium (Ru), or Tungsten (W), though examples are not so limited and vias can include any material known in the art. The vias and the conductive lines can be used to electrically connect devices (e.g., devices within the device layer 3007) to form a circuit that can be coupled to a power supply and additional circuits (internal or external to the semiconductor structure).

The BEOL wiring layer 3003 can be formed using techniques known in the art. In some embodiments, the FS BEOL wiring layer 3009 can be formed utilizing a dielectric stack deposition, masking, etching to form the conductive lines and/or via openings, metallization, and polishing, though embodiments are not so limited. In some embodiments, the BS BEOL wiring layer 3005 can be formed utilizing a dielectric deposition followed by masking to from the conductive lines and vias, though embodiments are not so limited. In still further embodiments, vias within the FS BEOL wiring layer 3009 and/or the BS BEOL wiring layer 3005 can be formed utilizing known lithography and etch processes (such as single or double damascene processing), though embodiments are not so limited.

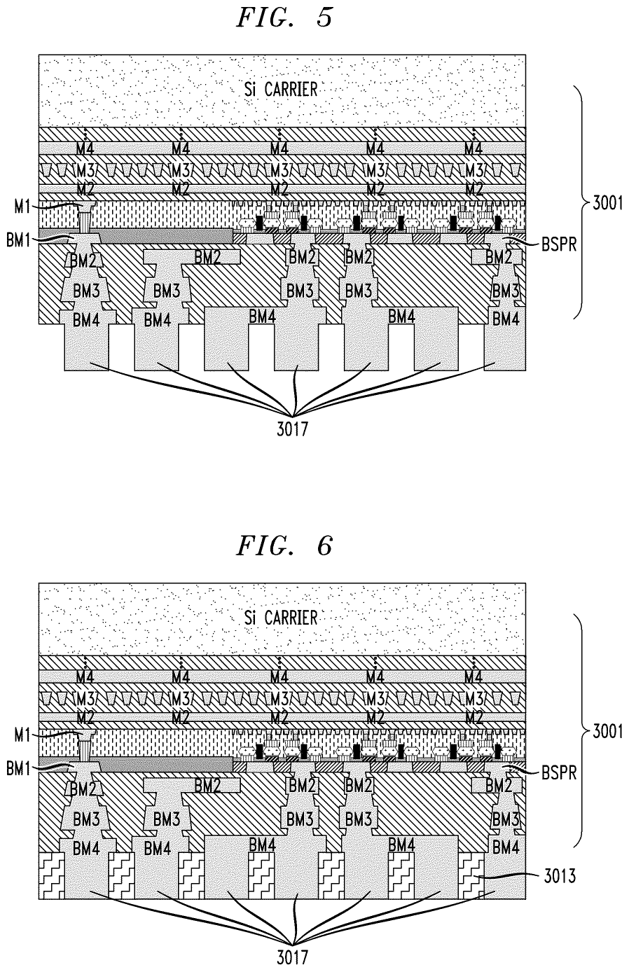

Turning now to FIG. 4, the plurality of pillars 3017 can be formed at the BS BEOL wiring layer of the BSPDN die 3001 utilizing a photo resist or dry-film lithography 3041 and a Cu electrochemical deposition (ECD) over a seed layer 3039 to result in pillar fabrication. In some embodiments, the formed plurality of pillars 3017 can include Cu, though embodiments are not so limited. After formation of the plurality of pillars 3017, the photo resist or dry-film can be stripped and the seed layer can be etched, as illustrated in FIG. 5. Polymer can be added to cover the plurality of pillars 3017, as shown in reference to FIG. 6; for example utilizing a spin-coat process. Utilizing processes known in the art, the polymer can be polished, etched back, and/or fly-cut to expose the plurality of pillars 3017 and can form a dielectric layer 3013 surrounding each pillar of the plurality of pillars 3017. In some embodiments, the method of manufacturing the semiconductor structure can further include a chemical mechanical polishing (CMP) of the plurality of pillars 3017.

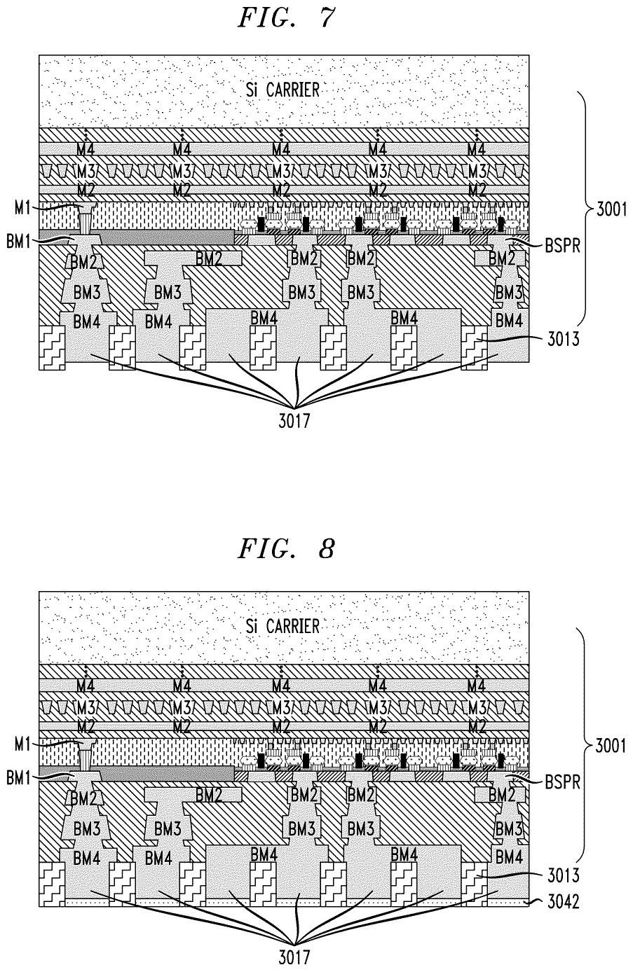

Continuing with FIG. 7, the plurality of pillars 3017 can be recessed. In some embodiments, the plurality of pillars 3017 can be recessed utilizing a wet etching process, though embodiments are not so limited. The etched surface of the plurality of pillars 3017 can be filled with a solder material 3043 as further illustrated in FIG. 8. In some embodiments, an injection molded solder (IMS) process can be utilized to fill the surface of the plurality of pillars 3017 with the solder material 3043.

Furthermore, in a non-limiting alternate process flow, using only plating processes, the plurality of pillars 3017 and a solder material 3043 can be both formed using the same photo-resist mask, such that the plurality of pillars 3017 with a solder cap (i.e., with solder material 3043) can be formed. As such, after formation of the plurality of pillars 3017 and the solder material 3043, the photo resist or dry-film can be stripped and the seed layer can be etched. Polymer can be added to cover the plurality of pillars 3017 and the solder material 3043, for example utilizing a spin-coat process. Utilizing processes known in the art, the polymer can be polished, etched back, and/or fly-cut to expose the solder material 3043 and can form the dielectric layer 3013 surrounding each pillar of the plurality of pillars 3017 and the solder material 3043.

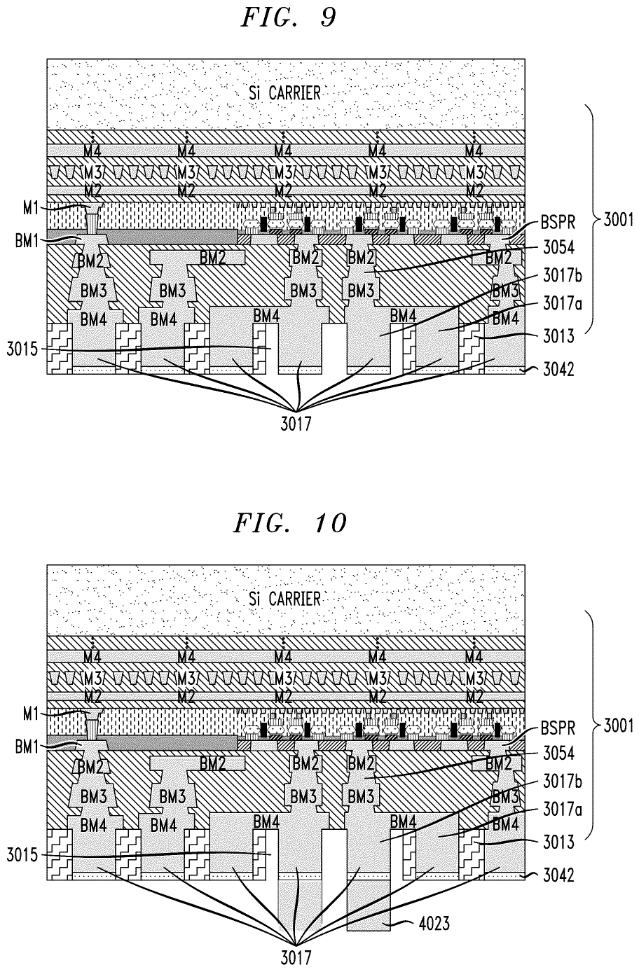

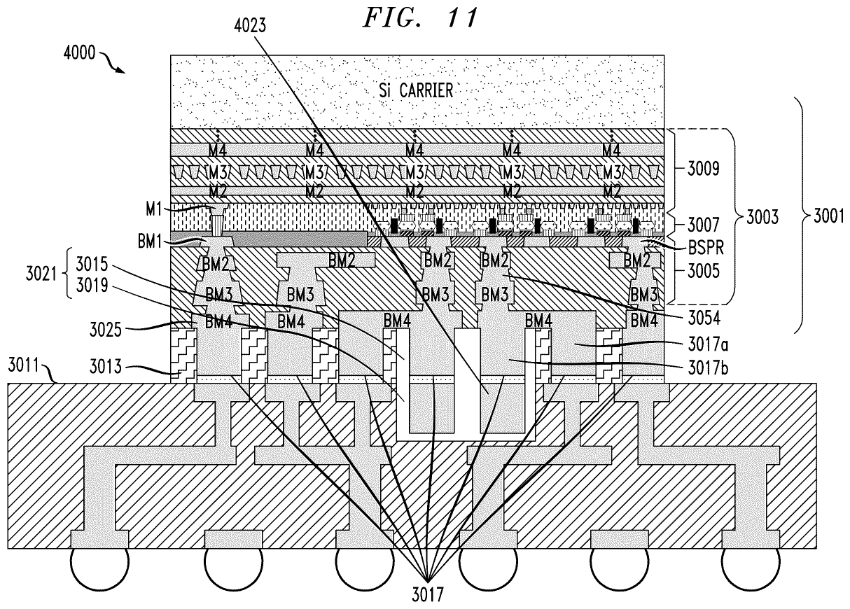

As shown in FIG. 9, the dielectric layer 3013 (the polymer) can be patterned to expose one or more pillars 3017b of the plurality of pillars 3017. The dielectric layer 3013 can be patterned utilizing reactive ion etching (RIE), laser ablation, or other processes known in the art. Patterning of the dielectric layer 3013 can create a recessed cavity 3015 (e.g., a partially or fully recessed cavity 3015) within the dielectric layer 3013. Accordingly, a first pillar 3017a of the plurality of pillars 3017 can be located in and surrounded by the dielectric layer 3013 and a second pillar 3017b of the plurality of pillars 3017 can reside within the recessed cavity 3015 within the dielectric layer 3013. In some embodiments, the patterning of the dielectric layer 3013 can coincide with one or more pillars thermally connected to the device layer of the BSPDN die 3001 through the BEOL wiring layer, such as the second pillar 3017b of the plurality of pillars 3017. The thermal connection between the device layer of the BEOL wiring layer and the second pillar 3017b can create a metal cooling/thermal dissipation path 3054 that can promote a release and dissipation of heat away from the device layer of the BSPDN die 3001. In some embodiments, the second pillar 3017b can be coupled to a power or a ground of the BEOL wiring layer. Further, in some nonlimiting embodiments, the solder material (solder material 3043 as shown in FIG. 8) can be optionally formed on the second pillar 3017b. That is, in some cases, the solder material can be excluded on one or more of the second pillars 3017b, though examples are not so limited.

Turning back to FIG. 2, in one embodiment, the BSPDN die 3001 can be coupled to a substrate 3011 (or package such as a substrate, an interposer, etc.). The substrate 3011 can include a cavity 3019. The dielectric layer 3013 and the substrate 3011 can be coupled so as the recessed cavity 3015 of the dielectric layer 3013 and the cavity 3019 of the substrate 3011 cooperatively forming a single cavity 3021. As such, the second pillar 3017b can reside within the single cavity 3021. Further, in one or more embodiments, the cavity 3019 of the substrate 3011 can be a cooling channel that includes a coolant inlet and a coolant outlet (e.g., cooling channel 8033, coolant inlet 7035, and coolant outlet 7037 of FIG. 15), as will be described in further detail here within. Accordingly, the metal cooling/thermal dissipation path 3054 can begin at the device layer 3007 of the BSPDN die 3001 and end in the cooling channel at the second pillar 3017b.

Referring now to FIG. 10, according to some aspects, in the method of manufacturing a semiconductor structure, according to the embodiment of FIG. 9, an extension pillar 4023 can be coupled to a second pillar 3017b of the plurality of pillars 3017. The extension pillar 4023 can extend from the second pillar 3017b, away from the BSPDN die 3001. In some embodiments, the extension pillar 4023 can be plated on top of the second pillar 3017b. In still further embodiments, the extension pillar 4023 can be soldered to the second pillar 3017b. The extension pillar 4023 can be soldered to the second pillar 3017b utilizing a pillar transfer process or with any other suitable thermally conductive material. Accordingly, the second pillar 3017b and the extension pillar 4023 can be thermally connected to the device layer of the BEOL wiring layer of the BSPDN die 3001. As such, the thermal connection between the device layer of the BEOL wiring layer and the extension pillar 4023 can create a metal cooling/thermal dissipation path 3054 that can promote a release and dissipation of heat away from the device layer of the BSPDN die 3001.

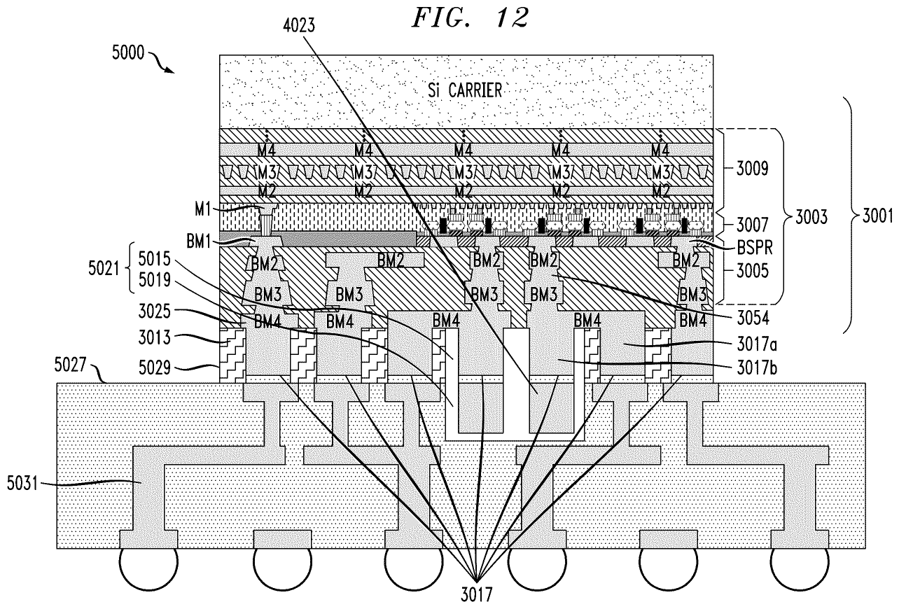

As shown in FIG. 11, the BSPDN die 3001 can then be coupled to a substrate 3011 to form a semiconductor structure 4000. The substrate 3011 can include a cavity 3019. The dielectric layer 3013 and the substrate 3011 can be coupled so that the recessed cavity 3015 of the dielectric layer 3013 and the cavity 3019 of the substrate 3011 cooperatively form a single cavity 3021. As such, the second pillar 3017b and the extension pillar 4023 can reside within the single cavity 3021. In some embodiments, the extension pillar 4023 can extend into the cavity 3019 of the substrate 3011. Further, in one or more embodiments, the cavity 3019 of the substrate 3011 can be a cooling channel that includes a coolant inlet and a coolant outlet (e.g., cooling channel 8033, coolant inlet 7035, and coolant outlet 7037 of FIG. 15), as will be described in further detail here within. As such, the metal cooling/thermal dissipation path 3054 can begin at the device layer 3007 of the BSPDN die 3001 and end in the cooling channel of the substrate 3011 at the extension pillar 4023.

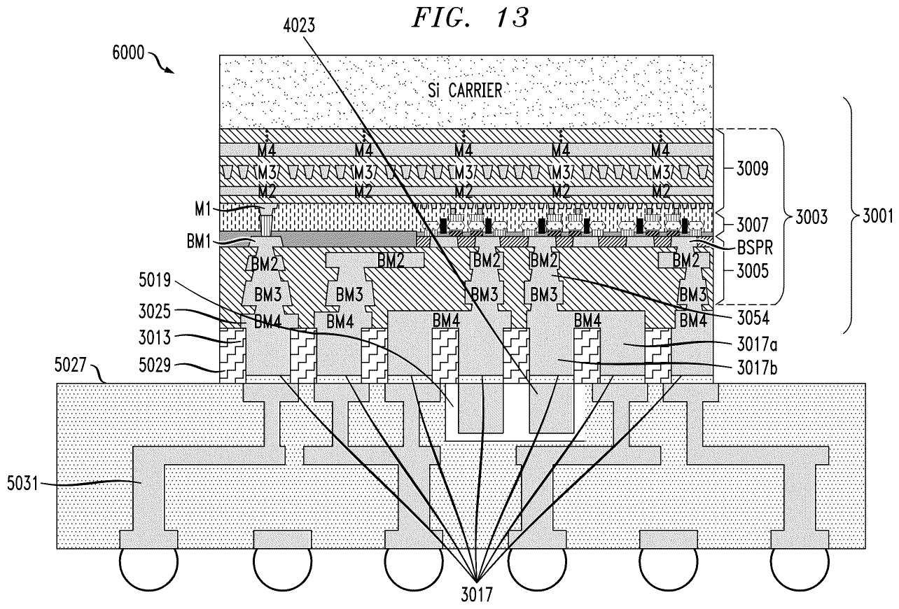

Turning now to FIG. 12, according to some aspects, in the method of manufacturing a semiconductor structure 5000, according to the embodiment of FIG. 10, the BSPDN die 3001 can be coupled to an interposer 5027. In some embodiments, the interposer 5027 can be hybrid bonded 5029 to the BSPDN die 3001, though examples are not so limited and other bonds, such as fusion bonding, can be contemplated. The hybrid bond 5029 (or fusion bond, etc.) can include a cavity 5015. The cavity 5015 of the hybrid bond 5029 can correspond to a recessed cavity of the dielectric layer (e.g., recessed cavity 3015 of dielectric layer 3013 as shown in FIGS. 9-11). The interposer 5027 can include a wiring layer 5031. The first pillar 3017a of the plurality of pillars 3017 can extend from the BPSDN die 3001 to the interposer 5027. In some embodiments, the first pillar 3017a can be electrically coupled to the wiring layer 5031 of the interposer 5027. Further, in some embodiments, the first pillar 3017a can be hybrid bonded 5029 to the interposer 5027.

In hybrid bonding, a permanent bond combines a dielectric bond (e.g., SiOₓ) with embedded metal (e.g., Cu) to form interconnections. Two dies, interconnect structures or semiconductor builds are joined together (e.g., two dies, semiconductor builds, or individual wafers that are built separately). They typically require a “pristine” surface (smooth and flat, possibly with some recesses), more so than traditional chemical-mechanical planarization (CMP). The two semiconductor builds are purposely designed to align. The term “hybrid” refers to the presence of both copper and dielectric. A bond that uses dielectric alone is referred to as fusion bonding (oxide to oxide, polymer to polymer, etc.). Hybrid bonding can use metal to metal connections for the copper. Two dies, interconnect structures or semiconductor builds are brought together facing each other and a small heat treatment/annealing process is carried out. The oxides bond together and the metals “anneal,” or almost melt, together, thus fusing the interface into a single bonded part (in some instances, seamlessly; i.e., the interface line disappears). In some embodiments, the solder material (e.g., solder material 3043 shown in FIG. 8) can be excluded and a Cu—Cu bond between chip and interposer can be created. Further, the hybrid bond 5029 can be a Cu-Oxide bond or when polymers are used can be a Cu-Polymer bond, though examples are not so limited.

In some embodiments, the interposer 5027 can include a cavity 5019. The cavity 5019 of the interposer 5027 can extend from a surface of the interposer 5027 and, at least partially, into the interposer 5027. The BSPDN die 3001 and the interposer 5027 can be coupled so as the cavity 5015 of the hybrid bond 5029 and the cavity 5019 of the interposer 5027 cooperatively forming a single cavity 5021. As such, the second pillar 3017b and the extension pillar 4023 can be embedded in or reside within the single cavity 5021. In some embodiments, the second pillar 3017b can, at least partially, reside within the cavity 5015 of the hybrid bond 5029 and the extension pillar 4023 can extend into and reside, at least partially in, the cavity 5019 of the interposer 5027. Further, in one or more embodiments, the cavity 5019 of the interposer 5027 can be a cooling channel that includes a coolant inlet and a coolant outlet (e.g., cooling channel 8033, coolant inlet 7035, and coolant outlet 7037 of FIG. 15), as will be described in further detail here within. As such, the metal cooling/thermal dissipation path 3054 can begin at the device layer 3007 of the BSPDN die 3001 and end in the cooling channel of the interposer 5027 at the extension pillar 4023.

Continuing with FIG. 13, according to some aspects, in the method of manufacturing a semiconductor structure 6000, according to the embodiment of FIG. 8, an extension pillar 4023 can be coupled to the second pillar 3017b of the plurality of pillars 3017. As illustrated in FIG. 13, the extension pillar 4023 can extend from the second pillar 3017b, away from the BSPDN die 3001. The BSPDN die 3001 can be coupled to an interposer 5027 at the plurality of pillars 3017. In some embodiments, the interposer 5027 can be hybrid bonded 5029 to the BSPDN die 3001. The interposer 5027 can include a wiring layer 5031. The first pillar 3017a of the plurality of pillars 3017 can extend from the BPSDN die 3001 to the interposer 5027. In some embodiments, the first pillar 3017a can be electrically coupled to the wiring layer 5031 of the interposer 5027.

Note, as shown in FIG. 13, some embodiments can include a non-patterned dielectric layer. That is, the first pillar 3017a and the second pillar 3017b of the plurality of pillars 3017 can be located in and surrounded by the dielectric layer (dielectric layer 3013 as shown in FIG. 8). Further, in some embodiments, the first pillar 3017a and the second pillar 3017b can be hybrid bonded 5029 to the interposer 5027.

In some embodiments, the interposer 5027 can include a cavity 5019. The cavity 5019 of the interposer 5027 can extend from a surface of the interposer 5027 and, at least partially, into the interposer 5027. In some embodiments, the extension pillar 4023 can extend into and reside, at least partially in, the cavity 5019 of the interposer 5027. Further, in one or more embodiments, the cavity 5019 of the interposer 5027 can be a cooling channel that includes a coolant inlet and a coolant outlet (e.g., cooling channel 8033, coolant inlet 7035, and coolant outlet 7037 of FIG. 15), as will be described in further detail here within. As such, the metal cooling/thermal dissipation path 3054 can begin at the device layer 3007 of the BSPDN die 3001 and end in the cooling channel of the interposer 5027 at the extension pillar 4023.

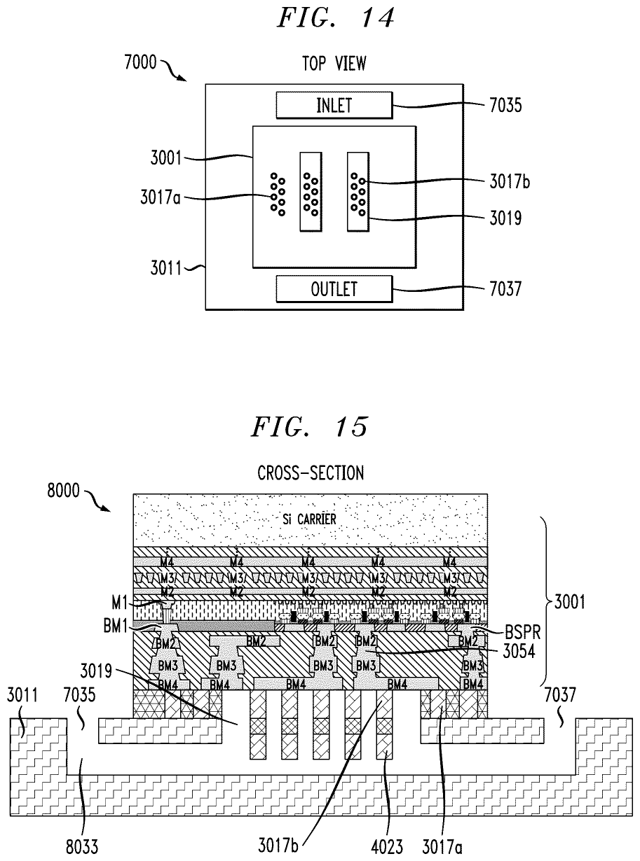

FIG. 14 illustrates a top view of a semiconductor structure 7000 including a backside power delivery network (BSPDN) die 3001 coupled to a substrate 3011 (or a package such as a substrate 3011, interposer 5027 as shown in FIG. 12 and FIG. 13, etc.) including a coolant inlet 7035 and a coolant outlet 7037. As previously described, in some embodiments a first pillar 3017a can be located in and surrounded by a dielectric layer of the BSPDN die 3001 and a second pillar 3017b can reside within a cavity 3019 of the substrate 3011 (or a cavity 5019 of the interposer 5027 as shown in FIG. 12 and FIG. 13). Additionally, in some embodiments, the second pillar 3017b can further reside within a recessed cavity of the dielectric layer, and in the case of a hybrid bond between the BSPDN die 3001 and the substrate 3011 (or interposer) a cavity of the hybrid bond. As illustrated in FIG. 15, some embodiments can further include multiple recessed cavities of the dielectric layer, multiple cavities of the hybrid bond, and/or multiple cavities 3019 of the substrate 3011 (or interposer).

As is shown in greater detail in reference to FIG. 15, the cavity 3019 of the substrate 3011 (or the cavity of the interposer) can be fluidically coupled to the coolant inlet 7035 and the coolant outlet 7037 to enable a metal cooling/thermal dissipation path for a device layer of the BSPDN die 3001, utilizing thermal connections of the BSPDN die 3001 to the second pillar 3017b. Further, it is contemplated in some embodiments, that the cavity 3019 of the substrate 3011 (or the cavity of the interposer) can extend from the coolant inlet 7035 to the coolant outlet 7037. Further, in some embodiments, the cavity of the dielectric layer and/or the cavity of the hybrid bond can extend from the coolant inlet 7035 to the coolant outlet 7037 (not shown), though examples are not so limited.

That is, as shown in greater detail in a cross-sectional view of a semiconductor structure 8000 of FIG. 15, a cooling channel 8033 can connect a coolant inlet 7035 to a coolant outlet 7037 of a substrate 3011 (or an interposer such as interposer 5027 shown in FIG. 12 and FIG. 13). As shown in FIG. 15, a plurality of pillars can extend from a backside power delivery network (BSPDN) die 3001 coupled to the substrate 3011. A first pillar 3017a of the plurality of pillars can be located in and surrounded by a dielectric layer of the BSPDN die 3001. In some embodiments, a second pillar 3017b of the plurality of pillars can include an extension pillar 4023, though examples are not so limited. The second pillar 3017b and/or the extension pillar 4023 can be exposed to a cavity 3019 in the substrate 3011 (or cavity 5019 of the interposer 5027 as shown in FIG. 12 and FIG. 13). The cavity 3019 of the substrate 3011 (or cavity of the interposer) can be fluidically coupled to the cooling channel 8033 and coolant (e.g., dielectric coolant) can flow from the coolant inlet 7035 across the exposed second pillar 3017b and/or extension pillar 4023 to the coolant outlet 7037. As previously stated, heat can be released and dissipated from a device layer of the BSPDN die 3001 through a metal cooling/thermal dissipation path 3054 created between the device layer and the cooling channel 8033. As illustrated in FIG. 15, the metal cooling/thermal dissipation path 3054 can include conductive lines and vias in a BEOL wiring layer, the second pillar 3017b, and, in some embodiments, the extension pillar 4023. Further, the metal cooling/thermal dissipation path 3054 can include the cavity 3019 of the substrate 3011 (or cavity of the interposer), and optionally the recessed cavity of the dielectric layer, and in some embodiments the cavity of the hybrid bond. Note that the flow paths can be configured with suitable headers and the like to route the cooling fluid in the spaces between the pillars to enhance convective heat transfer.

FIG. 16 illustrates a block diagram of a cooling system 9000 in accordance with the embodiments of FIG. 2 and FIGS. 11-15. In some embodiments, the cooling system 9000 can include a first reservoir 9044, a pump 9046, and a second reservoir 9052. The first reservoir 9044 can include a coolant such as a dielectric fluid, though examples are not so limited. The coolant can be pumped, via the pump 9046, from the first reservoir 9044 to a coolant inlet 7035 of a substrate 3011 (or an interposer) coupled to a backside power delivery network (BSPDN) die 3001. The coolant can travel though a cooling channel (e.g., cooling channel 8033 as shown in FIG. 15) to a coolant outlet 7037 of the substrate 3011 (or interposer) and out to the second reservoir 9052. In some embodiments, the first reservoir 9044 and the second reservoir 9052 can be separate reservoirs or separate chambers within a larger reservoir. In still further embodiments, the first reservoir 9044 and the second reservoir 9052 can be the same reservoir and fluid can loop through the first reservoir 9044, the substrate 3011 (or interposer), and the second reservoir 9052. In a closed-loop system, a heat exchanger (not shown) can be used to cool the fluid before passing it back into the system. An open loop approach could be employed for air cooling or the like.

In some embodiments, the cooling system 9000 can further include a flow meter/valve assembly 9048 coupled between the first reservoir 9044 and the substrate 3011 (or interposer) to control the rate of flow of the coolant through the cooling system 9000. Still further, in some embodiments, the cooling system 9000 can include a microfilter 9050 coupled between the first reservoir 9044 and the substrate 3011 (or interposer) utilized to remove unwanted particles in the coolant. FIG. 16 illustrates the microfilter 9050 located between the flow meter 9048 and the substrate 3011 (or interposer), though examples are not so limited and the microfilter 9050 can be located in any location advantageous to the cooling system 9000. Further, in a nonlimiting example, other thermal control schemes will be apparent to the skilled artisan.

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching.” For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method can utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that in one aspect, an exemplary semiconductor structure 3000, 4000, 5000, 6000, 7000, 8000 includes a backside power delivery network (BSPDN) 3001 having a back-end-of-line (BEOL) wiring layer 3003; a package 3011 coupled to the BSPDN 3001 proximate to the BEOL wiring layer 3003; a dielectric layer 3013 located between the BSPDN 3001 and the package 3011; a coolant inlet 7035 and a coolant outlet 7037; a cavity 3021 located within at least one of the package 3011 and the dielectric layer 3013, wherein the cavity 3021 is in fluid communication with the coolant inlet 7035 and the coolant outlet 7037; and a plurality of pillars 3017 coupled to and extending from the BSPDN 3001 at the BEOL wiring layer 3003, in which a first pillar 3017a, of the plurality of pillars 3017, is located in and surrounded by the dielectric layer 3013 and a second pillar 3017b, of the plurality of pillars 3017, resides within the cavity 3021. Technical benefits of a second pillar 3017b of the plurality of pillars 3017 extending from a BSPDN 3001 and residing within a cavity 3021 include a creation of a metal cooling/thermal dissipation path 3054 for heat, generated by the BSPDN 3001 during operation of the semiconductor structure 3000, 4000, 5000, 6000, 7000, 8000, to travel away from heat sensitive components of the BSPDN 3001 (e.g., a device layer 3007 of the BSPDN 3001) through the second pillar 3017b and into the cavity 3021. Further, the coolant inlet 7035 and the coolant outlet 7037 in fluid communication with the cavity 3021 can allow for a coolant, such as a dielectric coolant, introduced to the cavity 3021 and thus introduced to the second pillar 3017b, to enable further heat dissipation from the heat sensitive components of the BSPDN 3001 via the second pillar 3017b.

Optionally, the first pillar 3017a can be electrically connected to the BEOL wiring layer 3003 and electrically connected to the package 3011 coupled to the BSPDN 3001. Technical benefits of the first pillar 3017a being electrically connected between a BEOL wiring layer 3003 and a package 3011 is to enable electrical communication between the BEOL wiring layer 3003 and the package 3011.

Further, optionally, the BSPDN 3001 can further include a device layer 3007 and the second pillar 3017b can be thermally connected to the device layer 3007 of the BSPDN 3001. Technical benefits include further creation of the metal cooling/thermal dissipation path 3054 between a heat generating device layer 3007 of a BSPDN 3001 and the cavity 3021 in which the second pillar 3017b can reside, thus enabling an ability to dissipate heat, generated by the device layer 3007 during operation of the semiconductor structure 3000, 4000, 5000, 6000, 7000, 8000, away from the device layer 3007 and toward the cavity 3021.

In further options, the semiconductor structure 4000, 5000, 6000 further includes an extension pillar 4023 coupled to and extending from the second pillar 3017b. In some options, the second pillar 3017b and the extension pillar 4023 can be connected to the BEOL wiring layer 3003 and the extension pillar 4023 can extend into the cavity 3021. Further in some options, the BSPDN 3001 can further include a device layer 3007 and the second pillar 3017b and the extension pillar 4023 can be thermally connected to the device layer 3007 of the BSPDN 3001. Technical benefits include extending a metal cooling/thermal dissipation path 3054 by utilizing an extension pillar 4023 coupled to the second pillar 3017b. This extension can further ensure fluid communication between the device layer 3007 and the cavity 3021, for instance in embodiments where the cavity 3021 is located only within the package 3011 and an extension is thus advantageous.

In still further options, the extension pillar 4023 can be plated on top of the second pillar 3017b or can be coupled to the second pillar 3017b by solder.

Optionally, the semiconductor structure 3000, 4000, 5000, 6000, 8000 can include a cooling channel 8033 fluidically coupled to the coolant inlet 7035, the coolant outlet 7037, and the cavity 3021. Technical benefits of a cooling channel 8033 include enabling a coolant to flow between the coolant inlet 7035 and the coolant outlet 7037 further drawing heat away from the heat sensitive device layer 3007 through the metal cooling/thermal dissipation path 3054 created between the device layer 3007 and the second pillar 3017b.

In accordance with further aspects of the invention, a semiconductor structure 3000, 4000, 7000, 8000 includes a backside power delivery network (BSPDN) 3001 including a back-end-of-line (BEOL) wiring layer 3003, a substrate 3011 coupled to the BSPDN 3001 proximate to the BEOL wiring layer 3003, a cavity 3019 within the substrate 3011, one or more terminal pads 3025 connected to the BSPDN 3001, and one or more pillars 3017 coupled to the one or more terminal pads 3025 and extending from a surface of the BSPDN 3001 toward the cavity 3019 of the substrate 3011. Technical benefits of one or more pillars 3017 extending from a BSPDN 3001 and toward a cavity 3019 of a substrate 3011 coupled to the BSPDN 3001 include a creation of a metal cooling/thermal dissipation path 3054 for heat, generated by the BSPDN 3001 during operation of the semiconductor structure 3000, 4000, 7000, 8000, to travel away from heat sensitive components of the BSPDN 3001. Accordingly, heat can travel through the one or more pillars 3017 and into the cavity 3019 of the substrate 3011.

Optionally, the BSPDN 3001 can further include a device layer 3007 and the one or more pillars 3017 can be thermally connected to the device layer 3007 of the BSPDN 3001. Technical benefits include further creation of the metal cooling/thermal dissipation path 3054 between a heat generating device layer 3007 of a BSPDN 3001 and the cavity 3019, thus enabling an ability to dissipate heat, generated by the device layer 3007 during operation of the semiconductor structure 3000, 4000, 7000, 8000, away from the device layer 3007 and toward the cavity 3019.

Further, optionally, the semiconductor structure 3000, 4000, 8000 can further include a dielectric layer 3013 located between the BSPDN 3001 and the substrate 3011, the dielectric layer 3013 can include an, at least partially, recessed cavity 3015. In still further options, the cavity 3019 of the substrate 3011 and the recessed cavity 3015 of the dielectric layer 3013 cooperatively comprise a single cavity 3021 and the one or more pillars 3017 extends from the surface of the BSPDN 3001 into the single cavity 3021. Technical benefits of a dielectric layer 3013, including a recessed cavity 3015, include an extension of area, that is the single cavity 3021, in which heat, generated by components within the device layer 3007 of the BSPDN 3001, can dissipate, thus enhancing the capability of heat dissipation from the device layer 3007.

In other options, the semiconductor structure 3000, 4000, 7000, 8000 can further include a cooling channel 8033 including a coolant inlet 7035 and a coolant outlet 7037, wherein the cooling channel 8033 is in fluid communication with the cavity 3019 of the substrate 3011. Technical benefits of a cooling channel 8033 include enabling a coolant to flow between the coolant inlet 7035 and the coolant outlet 7037 further drawing heat away from the heat sensitive device layer 3007 through the metal cooling/thermal dissipation path 3054 created between the device layer 3007 and the second pillar 3017b.

In yet further aspects of the invention, a semiconductor structure 5000, 6000, 7000, 8000 includes a backside power delivery network (BSPDN) 3001 including a back-end-of-line (BEOL) wiring layer 3003; an interposer 5027 coupled to the BSPDN 3001 proximate to the BEOL wiring layer 3003; a cavity 5019 extending from a surface of the interposer 5027 and, at least partially, into the interposer 5027; and a plurality of pillars 3017, in which a first pillar 3017a, of the plurality of pillars 3017, extends from the BSPDN 3001 to the interposer 5027, in which the first pillar 3017a can be electrically connected to the BEOL wiring layer 3003 of the BSPDN 3001 and a wiring layer 5031 of the interposer 5027 and a second pillar 3017b, of the plurality of pillars 3017, can be coupled to and extend from the BSPDN 3001 toward the cavity 5019 of the interposer 5027. Technical benefits of a second pillar 3017b of the plurality of pillars 3017 extending from a BSPDN 3001 and toward a cavity 5019 of an interposer 5027 coupled to the BSPDN 3001 include a creation of a metal cooling/thermal dissipation path 3054 for heat, generated by the BSPDN 3001 during operation of the semiconductor structure 5000, 6000, 7000, 8000, to travel away from heat sensitive components of the BSPDN 3001 through the second pillar 3017b and into the cavity 5019 of the interposer 5027. Further, technical benefits of the first pillar 3017a being electrically connected between a BEOL wiring layer 3003 and a wiring layer 5031 of the interposer 5027 is to enable electrical communication between the BEOL wiring layer 3003 and the interposer 5027.

Optionally, the cavity 5019 of the interposer 5027 can be a cooling channel 8033 comprising a coolant inlet 7035 and a coolant outlet 7037. Technical benefits of a cooling channel 8033, including a coolant inlet 7035 and a coolant outlet 7037 in fluid communication with the cavity 5019 of the interposer 5027, can include allowing for a coolant introduced to the cavity 5019 to be introduced to the second pillar 3017b, enabling further heat dissipation from the heat sensitive components of the BSPDN 3001 via the second pillar 3017b.

Further, optionally, the first pillar 3017a and the second pillar 3017b can be hybrid bonded 5029 to the interposer 5027.

In still further options, the semiconductor structure 5000, 6000, 7000, 8000 can further include an extension pillar 4023 coupled to and extending from the second pillar 3017b and into the cavity 5019 of the interposer 5027. Technical benefits include extending the metal cooling/thermal dissipation path 3054 by utilizing an extension pillar 4023 coupled to the second pillar 3017b. This extension can further ensure fluid communication between the device layer 3007 and the cavity 5019 of the interposer 5027, for instance in embodiments where a recessed cavity 3015 of a dielectric layer 3013 located between the BSPDN 3001 and the interposer 5027 is excluded from the embodiment, though examples are not so limited.

In yet another option, the semiconductor structure 5000, 6000, 7000, 8000 can further include a dielectric layer 3013 located between the BSPDN 3001 and the interposer 5027. Optionally, the dielectric layer 3013 can include a recessed cavity 5015 around the second pillar 3017b and in which the second pillar 3017b can reside, at least partially, within the recessed cavity 5015 of the dielectric layer 3013 and the extension pillar 4023 can reside, at least partially, within the cavity 5019 of the interposer 5027. Further, optionally, the first pillar 3017a can be hybrid bonded to the interposer 5027. Technical benefits of a dielectric layer 3013, including a recessed cavity 3015, include an extension of area, that is the recessed cavity 5015 of the dielectric layer 3013 in cooperation with the cavity 5019 of the interposer 5027, in which heat generated by components within the device layer 3007 of the BSPDN 3001, can dissipate, thus enhancing the capability of heat dissipation from the device layer 3007.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of an exemplary backside power delivery network with pillar embedded in cooling channel as disclosed herein.

An integrated circuit in accordance with aspects of the present inventions can be employed in essentially any application and/or electronic system where one or more aspects of the exemplary backside power delivery network (BSPDN) with pillar embedded in cooling channel as disclosed herein would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom,” “top,” “above,” “over,” “under,” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a backside power delivery network (BSPDN) comprising a back-end-of-line (BEOL) wiring layer;
a package coupled to the BSPDN proximate to the BEOL wiring layer;
a dielectric layer located between the BSPDN and the package;
a coolant inlet and a coolant outlet;
a cavity located within at least one of the package and the dielectric layer, wherein the cavity is in fluid communication with the coolant inlet and the coolant outlet; and
a plurality of pillars coupled to and extending from the BSPDN at the BEOL wiring layer,
wherein:
a first pillar, of the plurality of pillars, is located in and surrounded by the dielectric layer; and
a second pillar, of the plurality of pillars, resides within the cavity.

2. The semiconductor structure of claim 1, wherein the first pillar is electrically connected to the BEOL wiring layer and electrically connected to the package coupled to the BSPDN.

3. The semiconductor structure of claim 1, wherein the BSPDN further comprises a device layer and the second pillar is thermally connected to the device layer of the BSPDN.

4. The semiconductor structure of claim 1, further comprising an extension pillar coupled to and extending from the second pillar.

5. The semiconductor structure of claim 4, wherein the second pillar and the extension pillar are connected to the BEOL wiring layer and the extension pillar extends into the cavity.

6. The semiconductor structure of claim 4, wherein the BSPDN further comprises a device layer and the second pillar and the extension pillar are thermally connected to the device layer of the BSPDN.

7. The semiconductor structure of claim 4, wherein the extension pillar is plated on top of the second pillar or is coupled to the second pillar by solder.

8. The semiconductor structure of claim 1, further comprising a cooling channel fluidically coupled to the coolant inlet, the coolant outlet, and the cavity.

9. A semiconductor structure comprising:
a backside power delivery network (BSPDN) comprising a back-end-of-line (BEOL) wiring layer;
a substrate coupled to the BSPDN proximate to the BEOL wiring layer;
a cavity within the substrate;
one or more terminal pads connected to the BSPDN; and
one or more pillars coupled to the one or more terminal pads and extending from a surface of the BSPDN toward the cavity of the substrate.

10. The semiconductor structure of claim 9, wherein the BSPDN further comprises a device layer and the one or more pillars are thermally connected to the device layer of the BSPDN.

11. The semiconductor structure of claim 9, further comprising a dielectric layerlocated between the BSPDN and the substrate, the dielectric layer comprising an, at least partially, recessed cavity.

12. The semiconductor structure of claim 11, wherein the cavity of the substrate and the recessed cavity of the dielectric layer cooperatively comprise a single cavity and the one or more pillars extends from the surface of the BSPDN into the single cavity.

13. The semiconductor structure of claim 9, further comprising a cooling channel comprising a coolant inlet and a coolant outlet, wherein the cooling channel is in fluid communication with the cavity of the substrate.

14. A semiconductor structure comprising:
a backside power delivery network (BSPDN) comprising a back-end-of-line (BEOL) wiring layer;
an interposer coupled to the BSPDN proximate to the BEOL wiring layer;
a cavity extending from a surface of the interposer and, at least partially, into the interposer; and
a plurality of pillars, wherein:
a first pillar, of the plurality of pillars, extends from the BSPDN to the interposer, wherein the first pillar is electrically connected to the BEOL wiring layer of the BSPDN and a wiring layer of the interposer; and
a second pillar, of the plurality of pillars, is coupled to and extends from the BSPDN toward the cavity of the interposer.

15. The semiconductor structure of claim 14, wherein the cavity of the interposer is a cooling channel comprising a coolant inlet and a coolant outlet.

16. The semiconductor structure of claim 14, wherein the first pillar and the second pillar are hybrid bonded to the interposer.

17. The semiconductor structure of claim 14, further comprising an extension pillar coupled to and extending from the second pillar and into the cavity of the interposer.

18. The semiconductor structure of claim 17, further comprising a dielectric layer located between the BSPDN and the interposer.

19. The semiconductor structure of claim 18, wherein the dielectric layer comprises a recessed cavity around the second pillar and wherein the second pillar resides, at least partially, within the recessed cavity of the dielectric layer and the extension pillar resides, at least partially, within the cavity of the interposer.

20. The semiconductor structure of claim 19, wherein the first pillar is hybrid bonded to the interposer.
